(19) United States
(12) Patent Application Publication
(10) Pub. No.: US 2006/0000642 A1
(43) Pub. Date: Jan. 5, 2006

(54) Interposer with compliant pins

(75) Inventor: Larry E. Dittmann, Middletown, PA (US)

Correspondence Address: PILLSBURY WINTHROP SHAW PITTMAN LLP, 1650 TYSONS BOULEVARD, MCLEAN, VA, 22102, US

(73) Assignee: EPIC Technology Inc., Sunnyvale, CA (US)

(21) Appl. No.: 10/894,607

(22) Filed: Jul. 20, 2004

Related U.S. Application Data
(60) Provisional application No. 60/584,895, filed on Jul. 1, 2004.

(51) Int. Cl. H05K 1/14

(52) U.S. Cl. 174/267; 174/262; 361/767

(57) ABSTRACT

An interposer is provided which includes a PCB having compliant pins connected to a first surface of the PCB. A plurality of vias located in the PCB are connected to the compliant pins and extend from the first surface toward a second surface of the PCB. A method for making an interposer is also provided.

This application claims priority to Provisional Patent Application No. 60/584,895 filed Jul. 1, 2004 which is herein incorporated by reference in its entirety.

### FIELD OF INVENTION

The present invention is related to printed circuit board (PCB) type connectors. More particularly, the present invention is directed to an interposer including a plurality of compliant pins that is suitable for use as a connector or carrier. The present invention also includes a method for making the interposer.

### BACKGROUND

Electronic components such as resistors, transistors, diodes, inductors, capacitors, packaged integrated circuits, and unpackaged dies must interface with other electronic components in an endless variety of systems. It would be desirable to provide a device which allows for electronic components to connect in a mechanically convenient manner, yet provides a high level of electrical performance and scalability.

### BRIEF DESCRIPTION OF THE DRAWING(S)

FIG. 1 is a cross-sectional elevation view of an interposer according to a preferred embodiment of the invention.

FIG. 1a is a cross-sectional elevation view showing an installation detail of the interposer in the form of a carrier including an electronic component according to a preferred embodiment of the invention.

FIG. 2 is a perspective view of a sheet of conductive and resilient material for forming at least one, and more preferably an array of compliant pins according to a preferred embodiment of the invention.

FIG. 3 is a perspective view of a portion of the conductive and resilient material sheet representative of each of the areas depicted in dashed line in FIG. 2.

FIG. 4 is a perspective view of the sheet portion of FIG. 3 which has been deep drawn to form a body.

FIG. 5 is a perspective view of the body with an end of the body being removed.

FIG. 6 is a perspective view, partially in cross-section, of the completed compliant pin.

FIG. 7 is a perspective view of the completed compliant pin.

FIG. 8 is a perspective view of an alternative embodiment of the compliant pin having additional side wall slits.

FIG. 9 is a flowchart depicting a process for creating a compliant pin package according to a preferred embodiment of the present invention.

### DETAILED DESCRIPTION OF THE PREFERRED EMBODIMENT(S)

The present invention will be described with reference to the drawing figures wherein like numerals represent like elements throughout. The terms “down”, “up”, “bottom”, “side” or “top” as used hereinafter are used only for convenience to differentiate certain aspects of the preferred embodiments in the orientation shown in the figures. It should be understood that these terms are not meant to limit the functional aspects of the elements to which the terms apply.

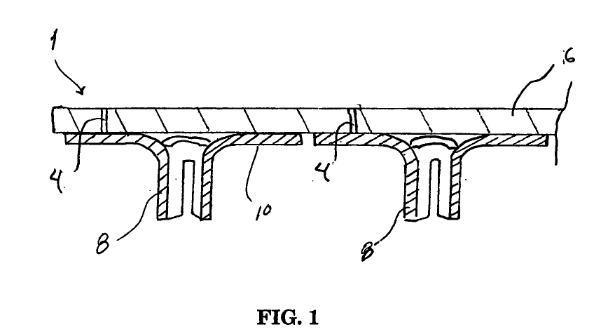

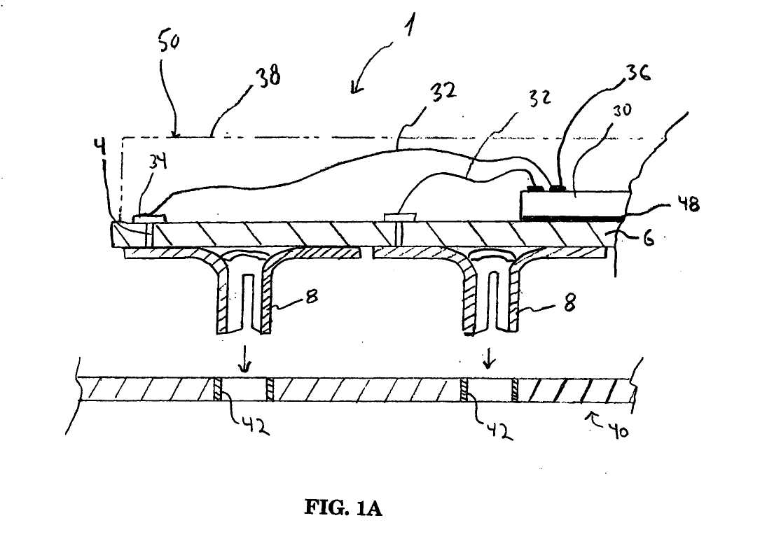

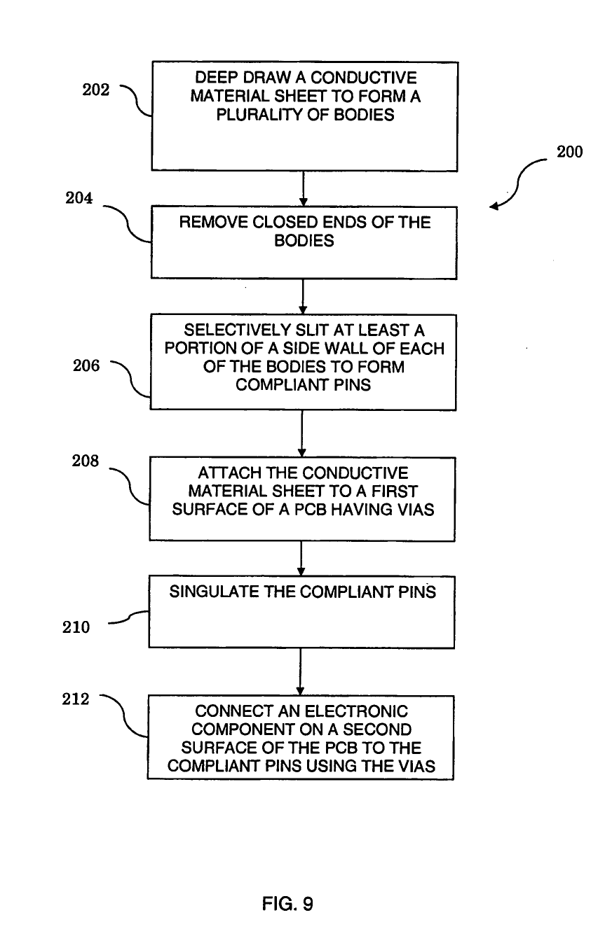

Referring to FIGS. 1 and 9, the present invention provides an interposer 1 and a method for making the interposer 1. The interposer 1 includes a printed circuit board (PCB) 6 and a plurality of compliant pins 8 adhered thereto. The PCB 6 includes vias 4 which provide a path between the compliant pins 8 and a top surface of the PCB 6.

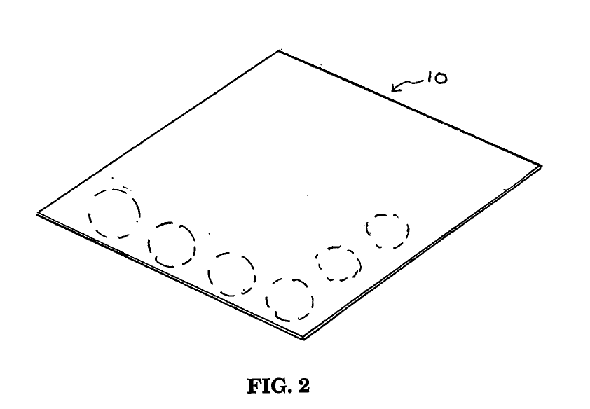

The compliant pins 8 are preferably fabricated from a single sheet of conductive and resilient material such as copper (Cu) or beryllium copper (BeCu). Alternatively, brass, phosphorous bronze or other suitable alloys may also be used. Referring to FIG. 2, a sheet 10 of conductive and resilient material is shown. Although the sheet 10 is shown as being configured in a generally square shape having a certain thickness, those of skill in the art should realize that this is for convenience of explanation and the shape and/or thickness of the sheet 10 will vary depending upon the particular application and the desired physical characteristics of the compliant pin. Such physical characteristics, for example, may include the impedance of the compliant pin, the desired normal force to be applied by the compliant pin and the working range of the compliant pin. The length and width of the compliant pin, as well as the distance between adjacent ones of the pins (i.e. the pitch) are also factors used in the selection of material composition and thickness.

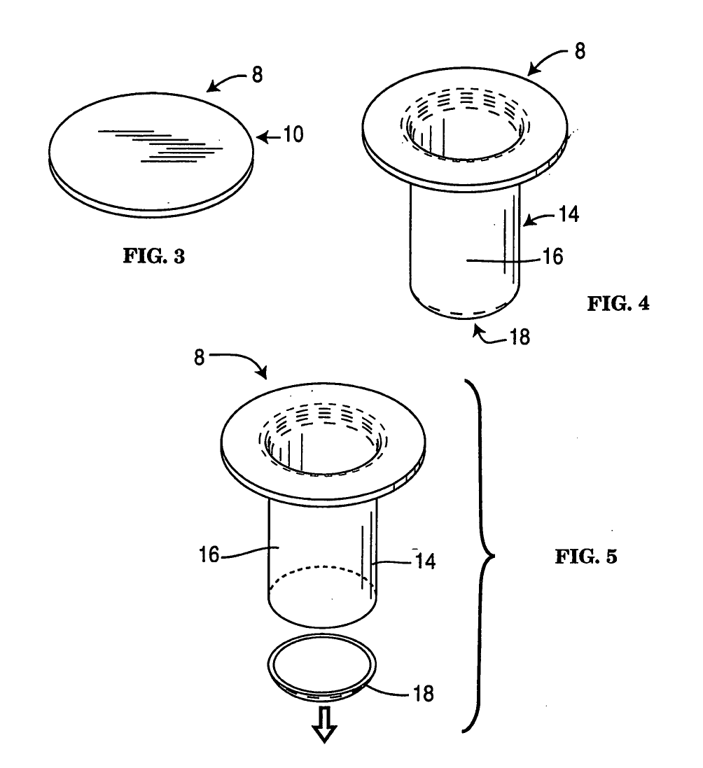

Referring to FIG. 3, a partial view of the sheet 10, representative of each of circular areas depicted in dashed line in FIG. 2, is shown. This portion of the sheet 10 corresponds to the areas in which each of the compliant pins 8 is formed.

The sheet 10 is drawn to form one or more cavities using a deep drawing process as shown in FIG. 4. Deep drawing is a well known process to those of skill in the metallurgical arts and, therefore, a detailed description of the process will not be set forth in detail hereinafter. Generally, however, deep drawing selectively stretches a sheet of material to form a desired three-dimensional shape. The cylindrical shape as shown in FIG. 4 and the subsequent Figures is for example only and the shape may be any shape desired for the particular application. For example, the body 14 may be substantially rectilinear in shape, or may be drawn much deeper or much more shallow than shown.

The body 14 generally comprises one or more side walls 16 and a bottom 18. The body 14 shown in the figures is substantially cylindrical and slightly tapered toward the bottom to allow easier insertion, and comprises a single continuous wall 16. However, the body 14 could also be a cubic or other three-dimensional shape, so that there may be a plurality of side walls 16. Likewise, although a bottom 18 is shown, a deep drawing process may be used such that there is no bottom 18 to the body 14.

If the body 14 includes a bottom 18, the bottom 18 may optionally be removed as shown in FIG. 5. This step is preferably used when it is desired to have a compliant pin with an extended operating range. As such, removing the bottom 18 from the body 14 would have certain operational advantages, although this step is optional and is not required for the compliant pin 8 to operate properly.

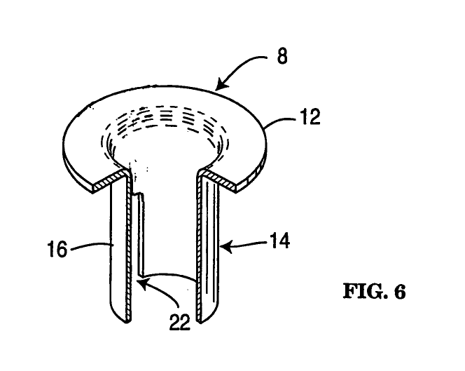

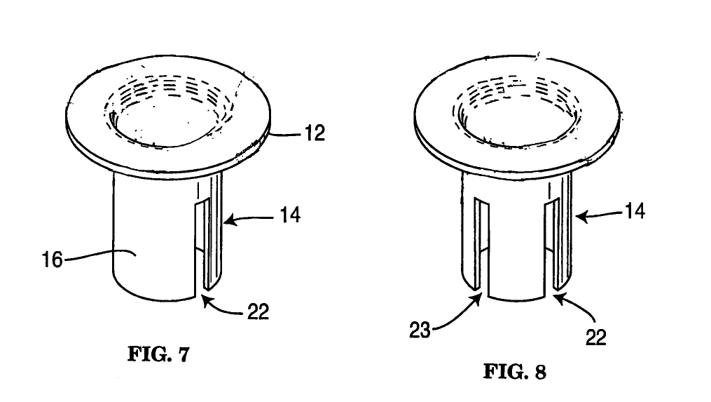

Referring to FIGS. 6 and 7, at least one slit is made in the wall 16 to form an opening 22. Although preferably at least one opening 22 is formed in the wall 16, any suitable number of openings can be formed, depending on the required insertion force and normal spring force desired. Referring to FIG. 9, for example, an additional opening 23 is added to provide added compliancy in the pin 8. Alternatively, the pins 8 may be provided without openings.

Referring again to FIG. 1, the completed sheet 10 with compliant pins 8 is attached to the PCB 6 to form the interposer 1, preferably using a suitable bonding adhesive such as polyimide, epoxy, silver-filled glass adhesive or other adhesives including pressure sensitive and heat cured adhesives. Depending on the particular application, one or more of the compliant pins 8 are then singulated, preferably using known etching techniques. Alternatively, mechanical or electrical techniques of singulating the compliant pins 8 may be used. Further, it is preferable to plate over the completed interposer 1 to establish electrical continuity between the pins 8 and the vias 4.

Referring to FIG. 1a, the interposer 1 may include an electronic component 50 connected to the PCB 6. In one preferred embodiment, the interposer 1 forms a carrier and the electronic component 50 is a die 30, enclosed by packaging material 38, attached to the PCB 6, preferably through use of a polyimide, epoxy or silver-filled glass adhesive 48. Bonding wires 32 are attached to bond pads 36 on the die 30. The bonding wires 32 extend from the bond pads 36 and attach to lead fingers or pads 34 on the PCB 6 which are connected to the vias 4. Alternatively, the die 30 may be electrically connected to the vias 4 by other known methods. Preferably, the die 30 and bonding wires 32 are covered by the packaging material 38 (represented by the phantom lines) which may include a plastic molding compound. Optionally, a die overcoat may be provided on the surface of the die 30 to reduce induced stresses in the die.

Alternatively, the electronic component 50 (represented by the phantom lines) may represent a resistor(s), transistor(s), diode(s), inductor(s), capacitor(s), and/or pre-packaged integrated circuit(s). Further, the electronic component 50 may include other connecting apparatus to allow other devices to connect with the interposer/carrier 1 though the electronic component 50.

The interposer/carrier 1 may be selectively connected to a second printed circuit board (second PCB) 40. Preferably, the compliant pins 8 are connectable with the plated through holes 42 of the second PCB 40. The compliant pins 8 provide a spring force radially outwardly against the perimeter of the holes 42 to removably retain the pins 8 in the holes. The removable connection may be made permanent through use of adhesive bonding or other known bonding methods. If openings 22, 23 are not provided in the pins 8, it is preferable the interposer be assembled using solder to attach the pins to the holes 42. In such an instance, the sheet 10 is preferably Copper (Cu) or a suitable Copper Alloy.

The interposer 1 may be connected with cables or other electronic devices. Further, the interposer 1 is a scalable device, and the compliant pins 8 and the PCB 6 may be enlarged or reduced in size to accommodate a variety of electronic devices of different sizes and applications.

Referring to FIG. 9, a method 200 for making a connector is shown. The method includes deep drawing a conductive material sheet to form a plurality of bodies (step 202), removing the closed ends of the bodies (step 204), and forming an opening in at least a portion of a side wall of each of the bodies to create compliant pins (step 206). The conductive material sheet is attached to a first surface of a PCB which includes vias (step 208). Preferably, the compliant pins are singulated (step 210). Optionally, some of the compliant pins may remain connected with other ones of the compliant pins as required by the particular application. An electronic component, such as the electronic component 50 of FIG. 1a, is connected to a second surface of the PCB and connected to the compliant pins using the vias (step 212).

One or more of the above-described steps may be omitted and/or performed in a different order. Further, while the preferred method is disclosed, the above-described embodiments of the interposer 1 and the components included therein are not limited by the preferred method. Any suitable method may be employed to construct the disclosed devices.

Although the present invention has been described in detail, it is to be understood that the invention is not limited thereto, and that various changes can be made therein without departing from the spirit and scope of the invention, which is defined by the attached claims.

What is claimed is:

1. An electrical interposer comprising:
a PCB;
a plurality of compliant pins connected to a first surface of the PCB, each of the compliant pins having a drawn body with at least one side wall extending along a given axis substantially perpendicular to the PCB; and
a plurality of vias located in the PCB connected to the compliant pins and extending toward a second surface of the PCB.

2. An electrical interposer comprising:
a PCB;
a plurality of compliant pins connected to a first surface of the PCB, each of the compliant pins having a drawn body with at least one side wall extending along a given axis substantially perpendicular to the PCB;
a plurality of vias located in the PCB connected to the compliant pins and extending toward a second surface of the PCB; and
an electronic component attached to the second surface of the PCB.

3. An electrical interposer comprising:
a PCB;
a plurality of compliant pins connected to a first surface of the PCB, each of the compliant pins having a drawn body with at least one side wall extending along a given axis substantially perpendicular to the PCB;
a plurality of vias located in the PCB connected to the compliant pins and extending toward a second surface of the PCB; and
an electronic component attached to the second surface of the PCB, the electronic component including a die attached to the PCB and an electrical connection between the die and at least one of the compliant pins.

4. An electrical interposer comprising:
a PCB;
a plurality of compliant pins connected to a first surface of the PCB, each of the compliant pins having a drawn body with at least one side wall extending along a given axis substantially perpendicular to the PCB;
a plurality of vias located in the PCB connected to the compliant pins and extending toward a second surface of the PCB;
an electronic component attached to the second surface of the PCB, the electronic component including a die attached to the PCB and an electrical connection between the die and at least one of the compliant pins; and
packaging material which protects the die and the electrical connection.

5. An electrical interposer comprising:
a PCB;
a plurality of compliant pins connected to a first surface of the PCB, each of the compliant pins having a drawn body with at least one side wall extending along a given axis substantially perpendicular to the PCB, and at least one side wall of at least one of the compliant pins having at least one opening substantially parallel to the given axis; and
a plurality of vias located in the PCB connected to the compliant pins and extending toward a second surface of the PCB.

6. An electrical interposer comprising:
a PCB;
a plurality of compliant pins connected to a first surface of the PCB, each of the compliant pins having a tapered drawn body with at least one side wall extending along a given axis substantially perpendicular to the PCB; and
a plurality of vias located in the PCB connected to the compliant pins and extending toward a second surface of the PCB.

7. A method for making an interposer comprising:
deep drawing a conductive material sheet to form a plurality of pin-shaped bodies having side walls;
providing a PCB;
attaching the conductive material sheet to a first surface of the PCB; and
singulating at least one of the plurality of pin-shaped bodies.

8. A method for making an interposer comprising:
deep drawing a conductive material sheet to form a plurality of pin-shaped bodies having side walls;
slitting at least a portion of at least one of the side walls of at least one of the plurality of bodies to form a compliant pin;
providing a PCB;
attaching the conductive material sheet to a first surface of the PCB; and
singulating at least one of the plurality of pin-shaped bodies.

9. A method for making an interposer comprising:
deep drawing a conductive material sheet to form a plurality of pin-shaped bodies having side walls;
providing a PCB;
attaching the conductive material sheet to a first surface of the PCB;
singulating at least one of the plurality of pin-shaped bodies; and
attaching an electronic component to the PCB.

10. A method for making an interposer comprising:
deep drawing a conductive material sheet to form a plurality of pin-shaped bodies having side walls;
providing a PCB;
attaching the conductive material sheet to a first surface of the PCB;
singulating at least one of the plurality of pin-shaped bodies; and
attaching a die to the PCB, and electrically connecting the die to at least one of the plurality of bodies.

11. A method for making an interposer comprising:
deep drawing a conductive material sheet to form a plurality of pin-shaped bodies having side walls;
providing a PCB with at least one via to electrically connect to at least one of the plurality of bodies;
attaching the conductive material sheet to a first surface of the PCB; and
singulating at least one of the plurality of pin-shaped bodies.

12. A combination device comprising:
a carrier including a first PCB and a plurality of deep drawn compliant pins connected to a first surface of the first PCB; and
a second PCB, including plated through apertures, which receives at least one of the compliant pins through a respective one of the through apertures, the at least one of the compliant pins making contact with at least a portion of the perimeter of the respective one of the apertures.

13. A combination device comprising:
a carrier including a first PCB and a plurality of deep drawn compliant pins connected to a first surface of the first PCB; and
a second PCB, including plated through apertures, which receives at least one of the compliant pins through a respective one of the through apertures, the at least one of the compliant pins making contact with at least a portion of the perimeter of the respective one of the apertures and maintaining an interference fit with the respective one of the apertures.

14. A combination device comprising:
a carrier including a first PCB and a plurality of deep drawn compliant pins connected to a first surface of the first PCB; and
a second PCB, including plated through apertures, which receives at least one of the compliant pins through a respective one of the through apertures, the at least one of the compliant pins attached to the respective one of the apertures using an adhesive.

15. A combination device comprising:
a carrier including a first PCB, a plurality of deep drawn compliant pins connected to a first surface of the first PCB, and an electronic component connected to the first PCB and connected to at least one of the compliant pins; and
a second PCB, including plated through apertures, which receives at least one of the compliant pins through a respective one of the through apertures, the at least one of the compliant pins making contact with at least a portion of the perimeter of the respective one of the apertures.
